(19) United States
(12) Patent Application Publication
(10) Pub. No.: US 2026/0337485 A1
(43) Pub. Date: Oct. 29, 2026

(54) LUMINOPHORE, METHOD FOR THE PRODUCTION OF A LUMINOPHORE AND RADIATION-EMITTING COMPONENT

(71) Applicant: AMS-OSRAM INTERNATIONAL GMBH, Regensburg (DE)

(72) Inventors: Markus SEIBALD, Kaufering (DE); Dominik BAUMANN, Munich (DE); Christiane STOLL, Schwabmuenchen (DE); Daniel WIMMER, Innsbruck (AT); Max Kilian RIESSBECK, Innsbruck (AT); Klaus WURST, Zirl (AT); Gunter HEYMANN, Hall in Tirol (AT); Hubert HUPPERTZ, lnnsbruck (AT)

(21) Appl. No.: 19/102,431

(22) PCT Filed: Aug. 2, 2023
(86) PCT No.: PCT/EP2023/071402

§ 371 Date: Feb. 10, 2025

(30) Foreign Application Priority Data
Aug. 11, 2022 (DE) 10 2022 120 309.3

(51) Int. Cl. C09K 11/77; H10H 20/01; H10H 20/851

(52) U.S. Cl. CPC C09K 11/77347; H10H 20/0361; H10H 20/8512

(57) ABSTRACT

A phosphor with the molecular formula MA₁₊ₓMB₅₋ₓD₂N₂O₄:E is specified, wherein MA is an element or a combination of elements selected from the group formed by Li, Na, K, Rb, and Cs, MB is an element or a combination of elements selected from the group formed by Li and Na, D is an element or a combination of elements selected from the group of tetravalent elements, E is at least one activator element, and 0≤x≤3 applies. A method for producing a phosphor and a radiation-emitting device are also specified.

### CROSS-REFERENCE TO RELATED APPLICATIONS

This is a national phase of International Application PCT/EP2023/071402, filed on Aug. 2, 2023, which claims priority to Germany Application DE 102022120309.3, filed on Aug. 11, 2022, the entire contents of each of these are incorporated herein by reference.

### TECHNOLOGICAL AREA

A phosphor and a method for producing a phosphor are specified. A radiation-emitting device is also described.

### BACKGROUND

It is inter alia an object to provide a phosphor comprising an increased efficiency. Furthermore, an efficient method for producing a phosphor and a radiation-emitting device with a high efficiency, in particular with a high color rendering index.

### SUMMARY

According to at least one embodiment, the phosphor comprises the molecular formula MA₁₊ₓMB₅₋ₓD₂N₂O₄:E. An alternative notation of the molecular formula is MA₁₊ₓ[MB₅₋ₓD₂N₂O₄]:E.

Here and in the following, phosphors are described using molecular formulas. The elements listed in the molecular formulas are present in charged form. Here and in the following, with reference to the molecular formulas of phosphors, elements and/or atoms therefore mean ions in the form of cations and anions, even if this is not explicitly specified. This also applies to element symbols if these are specified without a charge number for the sake of clarity.

It is possible that the phosphor comprises further elements, for example in the form of impurities, in the given molecular formulae. Taken together, these impurities comprise at most 5 mol %, in particular at most 1 mol %, for example at most 0.1 mol %.

The phosphor is generally uncharged on the outside. This means that there can be a complete charge balance between positive and negative charges on the outside of the phosphor. However, it is also possible that the phosphor formally does not comprise a complete charge balance to a small extent.

According to at least one embodiment of the phosphor, MA is an element or a combination of elements selected from the group formed by Li, Na, K, Rb, and Cs. In particular, MA is a monovalent cation. With other words, MA comprises a charge number of +1.

The term “valency” in relation to a specific element refers to how many elements with a single opposite charge are required in a chemical compound in order to achieve a charge balance. The term “valency” therefore comprises the charge number of the element.

According to at least one embodiment of the phosphor, MB is an element or a combination of elements selected from the group formed by Li and Na.

According to at least one embodiment of the phosphor, D is an element or a combination of elements selected from the group of tetravalent elements. Tetravalent elements are elements with a valency of four. Tetravalent elements are often positively charged four times in chemical compounds and have a charge number of +4. A charge balance in a chemical compound can take place, for example, via an element that is negatively charged four times, by two elements that are negatively charged twice, or four elements that are negatively charged once.

According to at least one embodiment of the phosphor, E is at least one activator element. In particular, the phosphor comprises a host structure into which foreign elements are introduced as activator elements. The host structure changes the electronic structure of the activator element such that electromagnetic radiation of an excitation wavelength, which is absorbed by the phosphor, causes an electronic transition from a ground state to an excited state in the phosphor. By emitting electromagnetic radiation with an emission spectrum, the phosphor returns to the ground state. The phosphor can comprise a single type of foreign element as an activator element or several types of foreign elements as activator elements.

According to at least one embodiment of the phosphor, 0≤x≤3 applies. For example x=1 or x=2 applies.

According to at least one embodiment, the phosphor comprises the molecular formula MA₁₊ₓMB₅₋ₓD₂N₂O₄:E, wherein MA is an element or a combination of elements selected from the group formed by Li, Na, K, Rb, and Cs, MB is an element or a combination of elements selected from the group formed by Li and Na, D is an element or a combination of elements selected from the group of tetravalent elements, E is at least one activator element and 0≤x≤3 applies.

In particular, the phosphor comprises an improved luminous efficacy of radiation. The luminous efficacy of radiation (LER) of the phosphor is the quotient of a luminous flux, the electromagnetic radiation emitted by the phosphor, and the radiant power of the electromagnetic radiation emitted by the phosphor. The greater the luminous efficacy of radiation, the greater the luminous flux that can be used by the eye for a given power.

According to at least one embodiment of the phosphor, D is an element or a combination of elements selected from the following group: Si, Ge, Sn, Ti, Zr. In particular, D is Si.

According to at least one embodiment of the phosphor, E is an element or a combination of elements selected from the following group: Eu, Ce, Mn, Cr, Ni, Bi, Tb, Yb. In particular, E is Ce and/or Eu. Eu is present in particular in the form Eu²⁺ or Eu³⁺. Ce is present in particular in the form Ce³⁺. Mn is present in particular in the form Mn⁴⁺. Cr is present in particular in the form Cr³⁺. Ni is present in particular in the form Ni²⁺. Bi is present in particular in the form Bi³⁺. Tb is present in particular in the form Tb³⁺. Yb is present in particular in the form Yb³⁺.

According to at least one embodiment of the phosphor, E comprises a proportion of between and including 0.01 mol % and 10 mol %, based on an added amount of substance of MA and MB. In particular, E comprises a proportion of between and including 0.1 mol % and 5 mol %, based on an added amount of MA and MB.

According to at least one embodiment of the phosphor, MA and MB comprise the same element. In particular, MA and MB comprise Li.

According to at least one embodiment of the phosphor, MA and MB are Li and x=1 or x=2 applies. In other words, the phosphor comprises the molecular formula Li₂Li₄Si₂N₂O₄:E or Li₃Li₃Si₂N₂O₄:E. Alternative notations for these molecular formulas are Li₂[Li₄Si₂N₂O₄]:E or Li₃[Li₃Si₂N₂O₄]:E. The double naming of Li reflects in particular that the Li atoms are differently coordinated in the host structure. The molecular formula according to this embodiment is summarized, for example, as Li₃SiNO₂:E.

According to at least one embodiment, a crystal structure of a host structure of the phosphor comprises a monoclinic or orthorhombic space group. In particular, the monoclinic space group is C2/c. The orthorhombic space group is, for example, Pbca. The phosphor with x=1 crystallizes, for example, in the monoclinic space group. The phosphor with x=2 crystallizes in particular in the orthorhombic space group.

The crystal structure is a description of the arrangement of atoms or ions in a crystalline material. The crystal structure is made up of a three-dimensional unit cell, which is generally repeated periodically. In other words, the unit cell is the smallest recurring unit of the crystal structure of the host structure. MA, MB, D, N, and O each occupy fixed positions in the unit cell, which are also referred to as point positions. In particular, E is often not taken into account when determining the crystal structure due to its insignificant contribution to the scattering density.

According to at least one embodiment of the phosphor, MA is present in the crystal structure of the host structure in a fivefold and/or sixfold coordinated state. This means, in particular, that an MA atom comprises five or six anions in its coordination sphere.

For example, a fivefold coordinated MA atom is trigonally bipyramidal surrounded by anions. In particular, the MA atom is surrounded by anions in a distorted trigonal bipyramidal manner. In other words, the anions form a distorted trigonal bipyramid around the MA atom. The crystal structure thus comprises distorted trigonal MA(N,O)₅ bipyramids. If spheres that touch each other in theory are placed in the corners of the trigonal bipyramid, a gap is formed which is occupied by the MA atom.

For example, a sixfold coordinated MA atom is surrounded octahedrally or distorted octahedrally by anions. In other words, the anions span an octahedron or a distorted octahedron around the MA atom. If spheres that touch each other in theory are placed in the corners of the octahedron, an octahedral gap is formed which is occupied by the MA atom.

In particular, the crystal structure of the phosphor comprises MA atoms with an octahedral coordination and MA atoms with a distorted octahedral coordination. The crystal structure comprises, for example, MA(N,O)₆ octahedra and/or distorted MA(N,O)₆ octahedra.

According to at least one embodiment of the phosphor, MB is present in the crystal structure of the host structure in a fourfold coordinated state. This means, in particular, that an MB atom comprises four anions in its coordination sphere. For example, MB is tetrahedrally coordinated. In other words, the anions form a tetrahedron around the MB atom. If spheres that touch each other in theory are placed in the corners of the tetrahedron, a tetrahedral gap is formed, which is occupied by the MB atom. The crystal structure thus comprises MB(N,O)₄ tetrahedra.

According to at least one embodiment of the phosphor, the crystal structure of the host structure comprises fourfold coordinated D atoms. In particular, the crystal structure comprises D(N,O)₄ tetrahedra.

According to at least one embodiment of the phosphor, the crystal structure of the host structure comprises at least two different layers. In particular, the at least two different layers are arranged alternately. For example, the crystal structure of the host structure of the phosphor comprises two or three different layers that are arranged alternately. The layers are connected to each other by corner and edge linking.

In particular, a first layer comprises dimers of MB(N,O)₄ tetrahedra. A dimer comprises two edge-linked MB(N,O)₄ tetrahedra. The MB(N,O)₄ tetrahedra in the dimer thus share two anions. The first layer also comprises in particular first chains. The first chains comprise corner-linked D(N,O)₄ tetrahedra. In the first layer, the dimers are, for example, corner- and edge-linked with the first chains. The dimers and the first chains are arranged alternately.

In particular, a second layer comprises second chains with MA(N,O)₆ octahedra. The MA(N,O)₆ octahedra are for example present edge-linked in the second chains. The second layer may further comprise third chains with MB(N,O)₄ tetrahedra, in particular with MBO₄ tetrahedra, and distorted MA(N,O)₆ octahedra. In the third chain, for example, the tetrahedra and octahedra are arranged alternately and are edge-linked. In particular, the second layer comprises fourth chains. The fourth chain comprises, for example, edge-linked MB(N,O)₄ tetrahedra, in particular edge-linked MBO₄ tetrahedra. In particular, the second layer comprises alternately arranged second, third, and fourth chains. The chains are edge-linked to each other. In the second layer, the chains are arranged, for example, in the following repeating sequence: second chain, third chain, fourth chain, third chain.

In particular, a third layer comprises fifth chains. The fifth chains comprise, for example, trigonal MA(N,O)₅ bipyramids that are edge-linked to one another. The third layer may further comprise sixth chains with corner-linked D(N,O)₄ tetrahedra. The fifth chains and the sixth chains are arranged alternately, for example, and are connected to each other in particular by corner and edge linking. In particular, the first chains and the sixth chains comprise the same structure.

For example, the phosphor with the monoclinic space group comprises two different layers. In particular, the first layer and the second layer of this phosphor are arranged alternately.

For example, the phosphor with the orthorhombic space group comprises three different layers. In particular, the layers are arranged in the following repeating sequence: first layer, second layer, third layer, second layer.

According to at least one embodiment, the phosphor absorbs electromagnetic radiation in the ultraviolet to blue spectral range. In particular, the phosphor absorbs electromagnetic radiation corresponding to the excitation wavelength. For example, the phosphor absorbs electromagnetic radiation in the wavelength range of between and including 300 nanometers and 500 nanometers.

According to at least one embodiment, an electromagnetic radiation emitted by the phosphor comprises an emission spectrum with an emission peak with an emission maximum in the wavelength range of between and including 545 nanometers and 645 nanometers, in particular in the wavelength range of between and including 560 nanometers and 620 nanometers, for example in the wavelength range of between and including 580 nanometers and 610 nanometers. In other words, the phosphor emits electromagnetic radiation in the orange spectral range.

The emission spectrum is an intensity distribution of the electromagnetic radiation emitted by the phosphor after excitation with electromagnetic radiation of the excitation wavelength. The emission spectrum is usually shown in the form of a diagram in which a spectral intensity or a spectral radiant flux per wavelength interval (“spectral intensity/spectral radiant flux”) of the electromagnetic radiation emitted by the phosphor is shown as a function of the wavelength λ. In other words, the emission spectrum represents a curve in a diagram in which the wavelength is plotted on the x-axis and the spectral intensity or spectral radiant flux is plotted on the y-axis.

Phosphors with an emission in the orange spectral range are used in general lighting, for example. For this, a low correlated color temperature (CCT), i.e. a correlated color temperature of at most 3500 K, in particular at most 3000 K, for example at most 2700 K, is advantageous. Such color temperatures can be achieved with the phosphor described here. Furthermore, the phosphor described here is used, for example, in applications with an even lower correlated color temperature, for example a correlated color temperature of at most 2400 K or of at most 2000 K. Such applications are in particular warm-white dimming, human-centric lighting applications, street lighting for residential areas and wildlife-friendly outdoor lighting.

During warm-white dimming, the correlated color temperature and brightness of a radiation-emitting device are reduced by a lower current flow. This advantageously imitates the behavior of thermal emitters such as incandescent lamps or natural sunlight. Human-centric lighting applications, for example, are characterized by a particularly low blue portion in their emission. This has the advantage of increasing the production of melatonin in the human body.

According to at least one embodiment, the electromagnetic radiation emitted by the phosphor comprises a dominant wavelength λ_{dom} between and including 535 nanometers and 635 nanometers, in particular between and including 560 nanometers and 610 nanometers, for example between and including 580 nanometers and 590 nanometers.

To determine the dominant wavelength of the electromagnetic radiation emitted by the phosphor, a straight line is drawn in the CIE standard diagram from the white point (x=0.333, y=0.333) through the color locus of the electromagnetic radiation. The intersection of the straight line with the spectral color line delimiting the CIE standard diagram denotes the dominant wavelength of the electromagnetic radiation. In general, the dominant wavelength deviates from the wavelength of the emission maximum.

According to at least one embodiment, the emission peak of the phosphor comprises a full width at half maximum between and including 80 nanometers and 110 nanometers, in particular between and including 85 nanometers and 110 nanometers, for example between and including 90 nanometers and 105 nanometers.

The full width at half maximum (FWHM) refers to a curve with a maximum, such as the emission spectrum, wherein the full width at half maximum is the region on the x-axis that corresponds to the two y-values corresponding to half of the maximum.

A method for producing a phosphor is further specified. In particular, the phosphor described herein is produced with the method. Features and embodiments described in combination with the phosphor therefore also apply to the method and vice versa.

According to at least one embodiment of the method for producing a phosphor, the phosphor has the molecular formula MA₁₊ₓMB₅₋ₓD₂N₂O₄:E, wherein MA is an element or a combination of elements selected from the group formed by Li, Na, K, Rb, and Cs, MB is an element or a combination of elements selected from the group formed by Li and Na, D is an element or a combination of elements selected from the group of tetravalent elements, E is at least one activator element, and 0≤x≤3 applies. The method comprises the steps of providing reactants, mixing the reactants to form a reactant mixture, and heating the reactant mixture. In particular, the steps are carried out in the specified order.

In particular, it is possible for the method to produce a mixture comprising or consisting of the phosphor. Further components of the mixture can be, for example, reactants which have not reacted during the production of the phosphor, impurities and/or secondary phases which were formed during the production.

According to at least one embodiment of the method, the reactants are selected from the following group: elements of MA, MB, D, and E, oxides of MA, MB, D, and E, nitrides of MA, MB, D, and E, fluorides of MA, MB, D, and E, and combinations thereof. In particular, the reactants are selected from a group consisting of Si, Si₃N₄, Li₂SiN₂, SiO₂, Li₂O, Li₃N, LiN₃, LiF, NaN₃, Eu, EuF₂, Eu₂O₃, EuF₃, EuN, Ce, CeF₃, CeN, CeO₂, and combinations thereof.

Other phosphors, in particular with orange emission, such as M₂Si₅N₈:Eu with M=Ca, Sr, Ba, are only produced with nitrides as reactants. These reactants are sensitive to oxidation and/or hydrolysis. In the method for producing a phosphor described here, oxides are also used as reactants in addition to nitrides. This advantageously makes the method less complex.

According to at least one embodiment of the method, the reactant mixture is heated to a temperature between and including 800 °C and 1100 °C. For producing other phosphors, such as M₂Si₅N₈:Eu with M=Ca, Sr, Ba, a significantly higher temperature, for example above 1500 °C, is in particular required. The method described here is therefore characterized by lower energy consumption compared to the production of the other phosphors.

According to at least one embodiment of the method, after heating the reactant mixture is cooled with a rate between and including 0.1 °C/min and 10 °C/min.

In particular, the temperature at which the reactant mixture is heated and the rate at which it is cooled adjust the crystal structure of the host structure of the phosphor. The phosphor with the host structure comprising a monoclinic space group is obtained, for example, at a temperature below 960 °C and rapid cooling, for example at a rate of at least 0.3 °C/min. The phosphor with a host structure comprising an orthorhombic space group is obtained, for example, at a temperature of at least 960 °C and with slow cooling, for example at a rate of at most 0.3 °C/min.

According to at least one embodiment of the method, the reactant mixture is heated under an inert gas atmosphere. For example, the reactant mixture is heated under an atmosphere of N₂.

According to at least one embodiment of the method, a flux is added to the reactant mixture. In particular, Li and/or LiF is added as flux. For example, about 5% by weight of flux is added to the reactant mixture. Advantageously, Li or LiF is used both as a reactant and as a flux in the method.

According to at least one embodiment of the method, the reactant mixture is heated for a time of between and including 1 hour and 100 hours, in particular for a time of between and including 4 hours and 20 hours.

A radiation-emitting device is further specified. Preferably, the phosphor described herein is suitable and intended for use in a radiation-emitting device described herein. Features and embodiments described with the phosphor and/or the method also apply to the radiation-emitting device and vice versa.

According to at least one embodiment, the radiation-emitting device comprises a semiconductor chip, which emits electromagnetic radiation of a first wavelength range during operation, and a conversion element with the phosphor described herein. The phosphor converts the electromagnetic radiation of the first wavelength range into electromagnetic radiation with an emission spectrum. The electromagnetic radiation of the first wavelength range serves in particular as the excitation wavelength of the phosphor.

The electromagnetic radiation with the emission spectrum is at least partially different from the electromagnetic radiation of the first wavelength range.

The radiation-emitting device is, for example, a light-emitting diode (LED).

In particular, the semiconductor chip comprises an epitaxially grown semiconductor layer sequence which contains an active region that generates the electromagnetic radiation of the first wavelength range during operation of the device. The semiconductor chip is, for example, a light-emitting diode chip or a laser diode chip. The electromagnetic radiation of the first wavelength range is emitted through a radiation exit surface of the semiconductor chip.

According to at least one embodiment of the radiation-emitting device, the semiconductor chip emits electromagnetic radiation in the blue to ultraviolet region of the electromagnetic spectrum during operation. For example, the semiconductor chip emits electromagnetic radiation with a dominant wavelength of about 447 nanometers.

According to at least one embodiment of the radiation-emitting device, the conversion element comprises no further radiation-converting component, such as a further phosphor.

According to at least one embodiment, the radiation-emitting device emits mixed light with a color temperature of at most 3500 K, in particular of at most 3000 K, preferably of at most 2700 K, for example of at most 2400 K or of at most 2000 K. In particular, the radiation-emitting device therefore emits warm white mixed light.

According to at least one embodiment, the radiation-emitting device emits mixed light with a color locus close to the Planckian curve. The Planckian curve is used in particular to determine the color temperature of a radiation-emitting device. The Planckian curve can be represented as part of the CIE standard diagram and is based on a Planckian radiator.

The phosphor described here in the conversion element can advantageously be used to provide a radiation-emitting device comprising a high color rendering index (CRI). In comparison with a radiation-emitting device with a nitride phosphor in the conversion element, a color rendering index that is about 14 points higher is observed for the same chromaticity coordinate.

Advantageously, the radiation-emitting device is used in general lighting and in particular in residential lighting, for warm-white dimming, in human-centric lighting applications, for street lighting in residential areas and for wildlife-friendly outdoor lighting. In street lighting in residential areas, an orange-emitting phosphor is used in the conversion element of the radiation-emitting device to create a color impression similar to that of sodium vapor lamps. Furthermore, by using the phosphor described here in the conversion element, a blue light portion is advantageously reduced in order to achieve wildlife-friendly outdoor lighting.

### BRIEF DESCRIPTION OF THE FIGURES

Further advantageous embodiments, configurations, and developments of the phosphor, the method for producing a phosphor and the radiation-emitting device are shown in the following exemplary embodiments illustrated with the figures.

FIG. 1 shows a schematic representation of a phosphor according to an exemplary embodiment.

FIGS. 2, 3A, 3B, 4A, 4B, 5, 6A, and 6B show schematic sections of a host structure of a phosphor according to two exemplary embodiments.

FIGS. 7 to 9 show analyses of powder diffractograms of phosphors according to two exemplary embodiments.

FIGS. 10 and 11 show excitation spectra and emission spectra of a phosphor, each according to an exemplary embodiment.

FIGS. 12 and 13 show emission spectra of a phosphor, each according to an exemplary embodiment.

FIGS. 14 and 15 show a temperature curve of an emission intensity of a phosphor, each according to an exemplary embodiment.

FIG. 16 schematically shows various steps of a method for producing a phosphor according to an exemplary embodiment.

FIG. 17 shows a schematic sectional view of a radiation-emitting device according to an exemplary embodiment.

FIGS. 18 and 19 show emission spectra of a radiation-emitting device according to an exemplary embodiment and a comparative example, respectively.

### DETAILED DESCRIPTION

Elements that are identical, similar, or have the same effect are marked with the same reference signs in the figures. The figures and the proportions of the elements shown in the figures should not be considered to be to scale. Rather, individual elements, in particular layer thicknesses, may be shown in exaggerated size for better visualization and/or understanding.

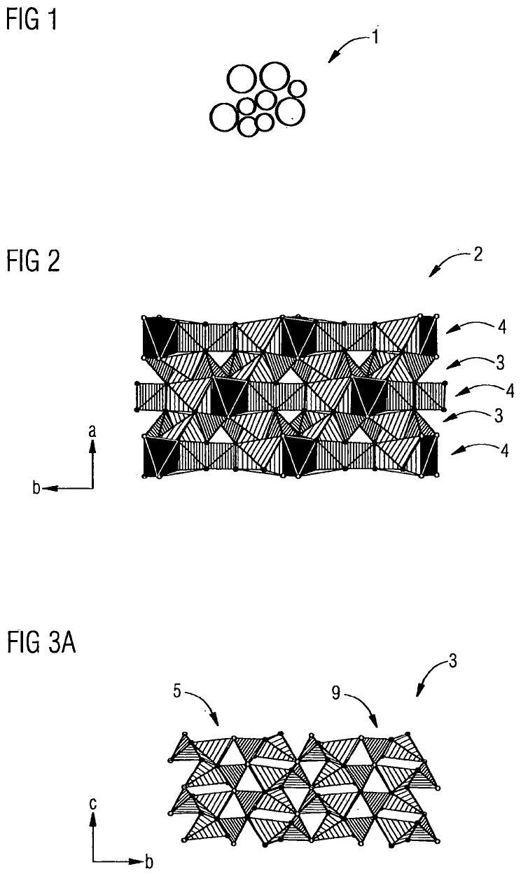

The phosphor 1 according to the exemplary embodiment of FIG. 1 has the molecular formula MA₁₊ₓMB₅₋ₓD₂N₂O₄:E, wherein MA is an element or a combination of elements selected from the group formed by Li, Na, K, Rb, and Cs, MB is an element or a combination of elements selected from the group formed by Li and Na, D is an element or a combination of elements selected from the group of tetravalent elements, E is at least one activator element, and x is greater than or equal to 0 and x is less than or equal to 3. The phosphor 1 is present in the form of particles comprising a particle size in the region of between and including 0.5 micrometers and 50 micrometers.

A section of a crystal structure of a host structure 2 of a phosphor 1 according to an exemplary embodiment is shown in FIG. 2. Presently, the phosphor 1 comprises the molecular formula MA₁₊ₓMB₅₋ₓD₂N₂O₄:E with x=1. MA and MB are Li, D is Si and E is Eu²⁺. The phosphor 1 therefore obeys the molecular formula Li₂[Li₄Si₂N₂O₄]:Eu²⁺. The phosphor 1 crystallizes in the monoclinic space group C2/c. Crystallographic data and positional parameters of the host structure 2 of the phosphor 1 according to the present exemplary embodiment are shown in Tables 1 and 2. The activator element E, presently Eu²⁺, is not taken into account in the determination of the crystal structure due to its insignificant contribution to the scattering density.

TABLE 1
Crystallographic data for Li₂[Li₄Si₂N₂O₄].

| Molecular formula | Li₂[Li₄Si₂N₂O₄]₄ |
|---|---|
| Crystal system | monoclinic |
| space group | C2/c (No. 15) |
| a/Å | 10.4901(3) |
| b/Å | 11.0342(3) |
| c/Å | 5.1186(2) |
| β/° | 116.142(2) |
| Cell volume/Å³ | 531.87(2) |
| T/K | 297(2) |
| Radiation/Å | Mo-Kα (λ = 0.71073) |
| Measuring range | 2.84 < θ < 40.25 |
| | −19 ≤ h ≤ 19 |
| | −20 ≤ k ≤ 20 |
| | −9 ≤ l ≤ 9 |
| Number of all reflexes | 24474 |
| Independent reflexes | 1622 |
| Number of parameters | 66 |
| Δρₘₐₓ, Δρₘᵢₙ/eÅ⁻³ | 0.516/−0.640 |
| R₁ (I ≥ 2σ(I)/all) | 0.0222/0.0226 |
| wR₂ (I ≥ 2σ(I)/all) | 0.0591/0.0594 |
| GooF | 1.147 |

TABLE 2
Crystallographic position parameters of Li₂[Li₄Si₂N₂O₄].

| Posi- | Wyckoff | | | | | Occu- |
|---|---|---|---|---|---|---|
| tion | symbol | x | y | z | U_{eq} | pation |
| Si1 | 8f | 0.22086(2) | 0.43007(2) | 0.25806(3) | 0.00621(6) | 1 |
| Li1 | 4e | 1/2 | 0.2978(2) | 1/4 | 0.0101(2) | 1 |
| Li2 | 4e | 1/2 | 0.4746(2) | 3/4 | 0.0153(3) | 1 |
| Li3 | 4e | 0 | 0.4338(2) | 3/4 | 0.0205(4) | 1 |
| Li4 | 4e | 0 | 0.3190(3) | 1/4 | 0.0188(4) | 0.76 |
| Li4A | 4e | 0 | 0.275(2) | 1/4 | 0.019(2) | 0.24 |
| Li5 | 8f | 0.2769(2) | 0.1976(2) | 0.2176(3) | 0.0198(3) | 1 |
| O1 | 8f | 0.12887(4) | 0.31224(3) | 0.05472(8) | 0.00791(8) | 1 |
| O2 | 8f | 0.38906(4) | 0.39292(5) | 0.3760(2) | 0.01470(9) | 1 |
| N1 | 8f | 0.17022(5) | 0.44522(4) | 0.5324(2) | 0.00872(8) | 1 |

The crystal structure in FIG. 2 is shown along the [001̅] direction. The crystal structure of the host structure 2 comprises a first layer 3 and a second layer 4. The first layer 3 and the second layer 4 are arranged alternately.

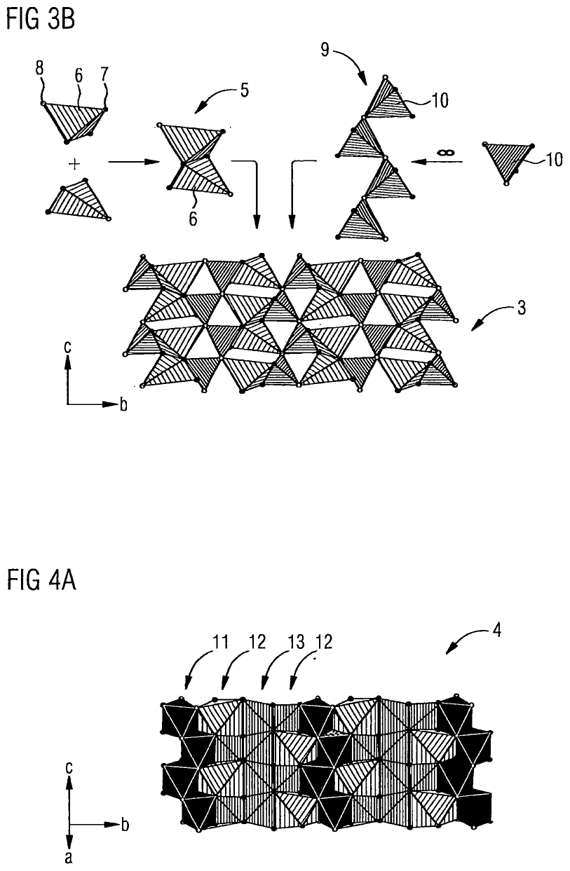

A section of the first layer 3 along the [1̅00] direction is shown in FIG. 3A. The structure of the first layer 3 consisting of different structural units is illustrated in FIG. 3B. The first layer 3 comprises dimers 5 of LiO₃N tetrahedra 6. The LiO₃N tetrahedra 6 are edge-linked in the dimers 5. A LiO₃N tetrahedron 6 is spanned by three O atoms 7 and one N atom 8. A Li atom is arranged in a tetrahedral gap of the LiO₃N tetrahedron 6. The first layer 3 further comprises first chains 9, which are formed with SiO₂N₂ tetrahedra 10. The SiO₂N₂ tetrahedra 10 are present corner-linked in the first chain 9. A SiO₂N₂ tetrahedron 10 is spanned by two O atoms 7 and two N atoms 8. The Si atom is arranged in a tetrahedral gap of the SiO₂N₂ tetrahedron 10. The dimers 5 are linked with the first chains 9 via the corners and edges of the LiO₃N tetrahedra 6 such that the first layer 3 is formed.

The arrangement of the structural units of the first layer corresponds to the arrangement of the structural units of Na₂Mn₂S₃ and Na₃In_{S}3. In this regard, the LiO₃N tetrahedra 6 correspond to the InS₄ tetrahedra or the MnS₄ tetrahedra (Mn2 layer) and the SiO₂N₂tetrahedra 10 correspond to the NaS₄ tetrahedra or the MnS₄ tetrahedra (Mn1 layer), respectively.

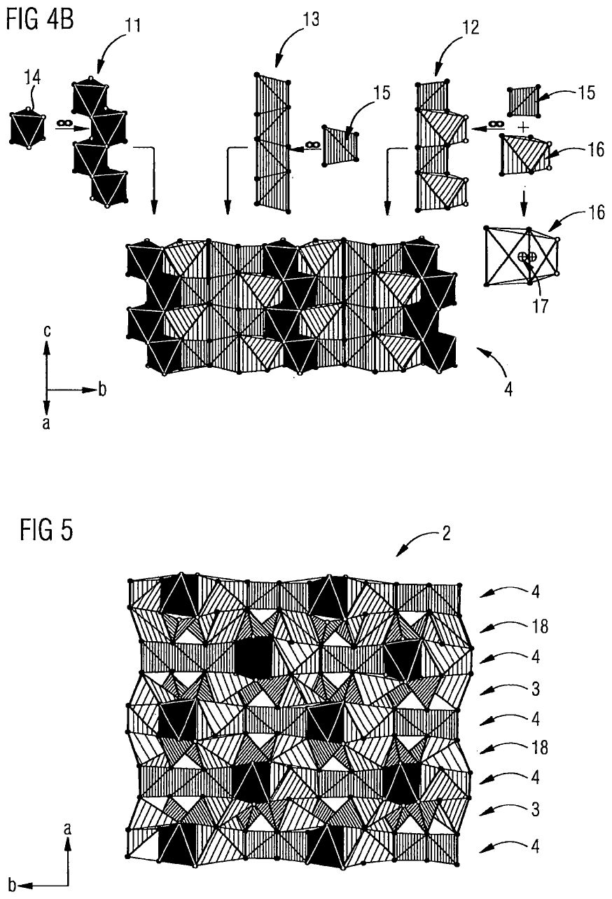

A section of the second layer 4 along the [1̅00] direction is shown in FIG. 4A. The structure of the second layer 4 consisting of different structural units is illustrated in FIG. 4B. The second layer 4 comprises second chains 11, third chains 12, and fourth chains 13. The second chains 11 comprise edge-linked LiO₂N₄ octahedra 14. A LiO₂N₄ octahedron 14 is spanned by two O atoms 7 and four N atoms 8. The Li atom is arranged in an octahedral gap of the LiO₂N₄ octahedron 14.

The third chains 12 comprise LiO₄ tetrahedra 15 and distorted LiO₄N₂ octahedra 16. A LiO₄ tetrahedron 15 is spanned by four O atoms 7. The Li atom is arranged in a tetrahedral gap of the LiO₄ tetrahedron 15. A LiO₄N₂ octahedron 16 is spanned by four O atoms 7 and two N atoms 8. A Li atom 17 is arranged in an octahedral gap of the LiO₄N₂ octahedron 16. Two different positions are observed for the Li atom 17 in the LiO₄N₂ octahedron 16. The Li atom 17 in the LiO₄N₂ octahedron 16 is therefore disordered. The LiO₄ tetrahedra 15 and the LiO₄N₂ octahedra 16 are arranged alternately in the third chain 12 and are linked to each other via their edges.

The fourth chains 13 comprise LiO₄ tetrahedra 15, which are linked to each other via their edges.

In the second layer 4, the chains 11, 12, 13 are arranged in the following repeating sequence: second chain 11, third chain 12, fourth chain 13, third chain 12. The chains 11, 12, 13 are linked in the second layer 4 via edges of the LiO₂N₄ octahedra 14, the LiO₄tetrahedra 15 and the LiO₄N₂ octahedra 16. The second layer 4 comprises only edge-linked coordination polyhedra.

The first layer 3 and the second layer 4 in the crystal structure of the host structure 2 of the phosphor 1 with the molecular formula Li₂[Li₄Si₂N₂O₄]:Eu²⁺ are linked with each other via corners and edges of the tetrahedra 6, 10, 15 and the octahedra 14, 16 (FIG. 2).

A section of a crystal structure of a host structure 2 of a phosphor 1 according to a further exemplary embodiment is shown in FIG. 5. Presently, the phosphor 1 comprises the molecular formula MA₁₊ₓMB₅₋ₓD₂N₂O₄:E with x=2. MA and MB are Li, D is Si and E is Eu²⁺. The phosphor 1 therefore obeys the molecular formula Li₃[Li₃Si₂N₂O₄]:Eu²⁺. The phosphor 1 crystallizes in the orthorhombic space group Pbca. Crystallographic data and position parameters of the host structure 2 of the phosphor 1 according to the present exemplary embodiment are shown in Tables 3 and 4. The activator element E, presently Eu²⁺, is not taken into account in the determination of the crystal structure due to its insignificant contribution to the scattering density.

TABLE 3
Crystallographic data of Li₃[Li₃Si₂N₂O₄].

| Molecular formula | Li₃[Li₃Si₂N₂O₄] |
|---|---|
| Crystal system | orthorhombic |
| space group | Pbca (No. 61) |
| a/Å | 18.736(2) |
| b/Å | 11.1267(5) |
| c/Å | 5.0897(3) |
| Cell volume/Å³ | 1061.0(2) |
| T/K | 297(2) |
| Radiation/Å | Mo-Kα (λ = 0.71073) |
| Measuring range | 2.17 < θ < 32 |
| | −27 ≤ h ≤ 27 |
| | −16 ≤ k ≤ 16 |
| | −7 ≤ l ≤ 7 |
| Number of all reflexes | 31987 |
| Independent reflexes | 1740 |
| Number of parameters | 128 |
| Δρₘₐₓ, Δρₘᵢₙ/eÅ⁻³ | 0.66/−0.37 |
| R₁ (I ≥ 2σ(I)/all) | 0.0380/0.0667 |
| wR₂ (I ≥ 2σ(I)/all) | 0.0778/0.0876 |
| GooF | 1.18 |

TABLE 4
Crystallographic position parameters of Li₃[Li₃Si₂N₂O₄].

| | Wyckoff | | | | | Occu- |
|---|---|---|---|---|---|---|
| Atom | symbol | x | y | z | U_{eq} | pation |
| Si1 | 8c | 0.98498(2) | 0.67984(4) | 0.77912(9) | 0.0139(2) | 1 |
| Si2 | 8c | 0.76185(2) | 0.67926(4) | 0.17250(9) | 0.0142(2) | 1 |
| 01 | 8c | 0.93831(6) | 0.5625(1) | 0.6622(2) | 0.0162(3) | 1 |
| 02 | 8c | 0.80930(6) | 0.5616(2) | 0.2822(2) | 0.0172(3) | 1 |
| 03 | 8c | 0.92996(6) | 0.3576(2) | 0.2543(3) | 0.0271(4) | 1 |
| 04 | 8c | 0.67784(7) | 0.6406(2) | 0.2235(3) | 0.0294(5) | 1 |
| N1 | 8c | 0.96029(8) | 0.6953(2) | 0.1021(3) | 0.0182(4) | 1 |
| N2 | 8c | 0.78618(8) | 0.6951(2) | 0.8473(3) | 0.0182(4) | 1 |
| Li1 | 8c | 0.8727(1) | 0.4583(2) | 0.4744(4) | 0.034(2) | 1 |
| Li2 | 8c | 0.8784(2) | 0.2302(2) | 0.4774(5) | 0.052(3) | 1 |
| Li3 | 8c | 0.8737(2) | 0.6835(3) | 0.4727(7) | 0.029(1) | 1 |
| Li4 | 8c | 0.8716(2) | 0.5746(5) | 0.9653(9) | 0.0274(9) | 0.78 |
| Li4a | 8c | 0.8726(8) | 0.518(2) | 0.965(3) | 0.027(3) | 0.22 |
| Li5 | 8c | 0.0145(2) | 0.4491(3) | 0.6983(6) | 0.034(2) | 1 |
| Li6 | 8c | 0.7489(2) | 0.4395(3) | 0.1270(7) | 0.023(1) | 1 |

FIG. 5 shows the crystal structure of the host structure 2 of phosphor 1 with the molecular formula Li₃[Li₃Si₂N₂O₄]:Eu²⁺ along the [001̅] direction. The crystal structure presently comprises a first layer 3, a second layer 4, and a third layer 18. The layers 3, 4, 18 are arranged in the following repeating sequence: first layer 3, second layer 4, third layer 18, second layer 4.

The first layer 3 has already been described with reference to FIGS. 3A and 3B, the second layer 4 with reference to FIGS. 4A and 4B.

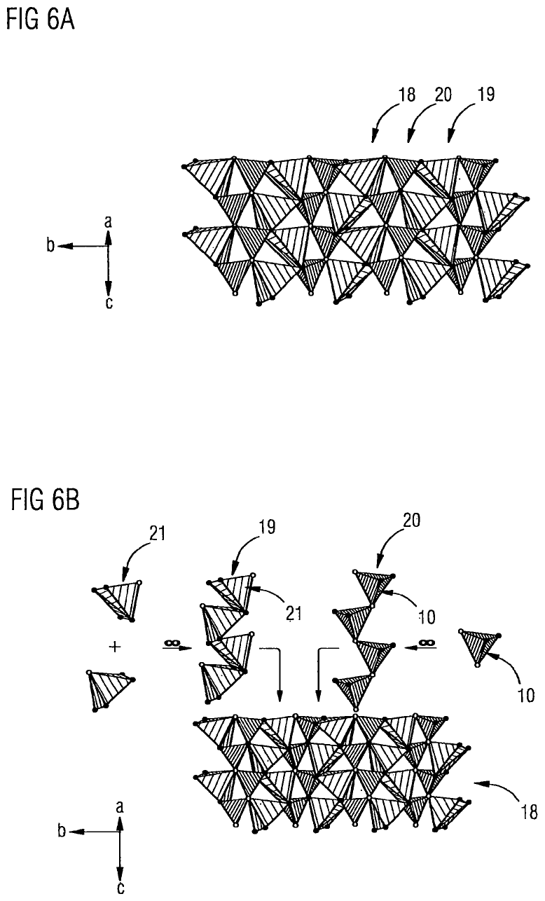

A section of the third layer 18 along the [1̅00] direction is shown in FIG. 6A. The structure of the third layer 18 consisting of different structural units is illustrated in FIG. 6B. The third layer 18 comprises alternately arranged fifth chains 19 and sixth chains 20. The fifth chains 19 comprise edge-linked distorted trigonal LiO₄N bipyramids 21. A trigonal LiO₄N bipyramid 21 is spanned by four O atoms 7 and one N atom 8. A base of the bipyramid 21 is spanned by two O atoms 7, one N atom 8, and one Li atom. The tips of the bipyramid 21 are formed by further O atoms 7. The sixth chains 20 comprise SiO₂N₂ tetrahedra 10. The SiO₂N₂ tetrahedra 10 are connected to each other via corner linking. The sixth chain 20 presently has the same structure as the first chain 9. In the third layer 18, the fifth chains 19 and the sixth chains 20 are linked to each other via corners and edges of the LiO₄N bipyramids 21 and the SiO₂N₂ tetrahedra 10.

In the crystal structure of the host structure 2 of phosphor 1 with the molecular formula Li₃[Li₃Si₂N₂O₄]:Eu²⁺, the first layer 3, the second layer 4, and the third layer 18 are linked via corners and edges of the tetrahedra 6, 10, 15, the octahedra 14, 16 and the bipyramids 21 (FIG. 5).

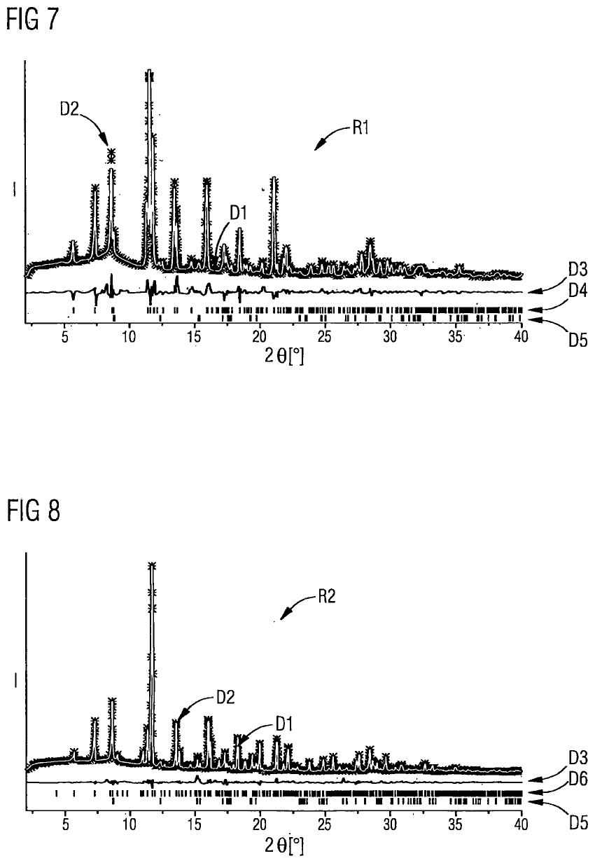

FIG. 7 shows a Rietveld-refined powder diffractogram R1 of a phosphor 1 according to an exemplary embodiment, presently Li₂[Li₄Si₂N₂O₄]:Eu²⁺. The intensity is plotted against the diffraction angle 2θ in degrees. The white line corresponds to the calculated diffractogram D1. The black stars represent the measured diffractogram D2. Line D3 is the difference plot of the values of curves D1 and D2. The markings D4 represent the theoretical reflection positions of Li₂[Li₄Si₂N₂O₄]:Eu²⁺. The markings D5 correspond to the theoretical reflection positions of LiSi₂N₃. The powder diffractogram R1 shows that in addition to phosphor 1 with the molecular formula Li₂[Li₄Si₂N₂O₄]:Eu²⁺, LiSi₂N₃ was also formed. The results of the Rietveld refinement are summarized in Table 5.

TABLE 5
Results of the RietveId refinement of a powder
sample of Li₂[Li₄Si₂N₂O₄]:Eu²⁺
Composition

| | |
|---|---|
| Li₂[Li₄Si₂N₂O₄]/wt % | 97(1) |
| LiSi₂N₃/wt % | 3(1) |

Crystallographic data

| | |
|---|---|
| Diffractometer | STOE STADI P |
| Radiation; wavelength/Å | Mo-Kα₁; 0.7093 |
| a/Å | 10.5484(7) |
| b/Å | 11.0305(8) |
| c/Å | 5.1254(4) |
| β/° | 116.661(4) |
| Cell volume/Å³ | 532.96(7) |
| 2 θ Region/° | 2-40 |
| 2 θ increment/° | 0.015 |
| Rₑₓₚ/% | 0.87 |
| R_{wp}/% | 7.80 |
| Rₚ/% | 5.35 |
| R_{Bragg}/% | 3.29 |

FIG. 8 shows a Rietveld-refined powder diffractogram R2 of a phosphor 1 according to another exemplary embodiment, presently Li₃[Li₃Si₂N₂O₄]:Eu²⁺. The intensity is plotted against the diffraction angle 2θ in degrees. The white line corresponds to the calculated diffractogram D1. The black stars represent the measured diffractogram D2. Line D3 is the difference plot of the values of curves D1 and D2. The markings D6 represent the theoretical reflection positions of Li₃[Li₃Si₂N₂O₄]:Eu²⁺. The markings D5 correspond to the theoretical reflection positions of LiSi₂N₃. The powder diffractogram R2 shows that in addition to phosphor 1 with the molecular formula Li₃[Li₃Si₂N₂O₄]:Eu²⁺, LiSi₂N₃ was also formed. The results of the Rietveld refinement are summarized in Table 6.

TABLE 6
Results of the RietveId refinement of a powder
sample of Li₃[Li₃Si₂N2O₄]:Eu²⁺.
Composition

| | |
|---|---|
| Li₃[Li₃Si₂N₂O₄]/wt % | 95.1(2) |
| LiSi₂N₃/wt % | 4.9(2) |

Crystallographic data

| | |
|---|---|
| Diffractometer | STOE STADI P |
| Radiation; wavelength/Å | Mo-Kα₁; 0.7093 |
| a/Å | 18.7462(5) |
| b/Å | 11.1270(4) |
| c/Å | 5.0897(2) |
| Cell volume/Å³ | 1061.66(5) |
| 2 θ Region/° | 2-40 |
| 2 θ increment/° | 0.015 |
| Rₑₓₚ/% | 1.78 |
| R_{wp}/% | 6.14 |
| Rₚ/% | 3.91 |
| R_{Bragg}/% | 2.10 |

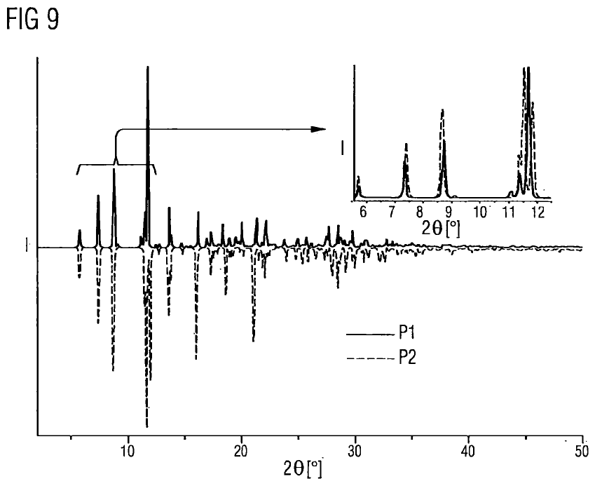

In FIG. 9 a simulated powder diffractogram P1 of Li₂[Li₄Si₂N₂O₄]:Eu²⁺and a simulated powder diffractogram P2 of Li₃[Li₃Si₂N₂O₄]:Eu²⁺ are shown. The powder diffractogram P1 is shown as a solid line, the powder diffractogram P2 as a dashed line. The powder diffractograms are simulated for Mo—Kα₁ radiation. The enlarged section at the top right shows examples of similarities, but also differences between the powder diffractograms P1 and P2. The similarities can be traced back to the common structural elements, namely the first layer 3 and the second layer 4, in the crystal structures of the host structures 2 of the phosphors 1.

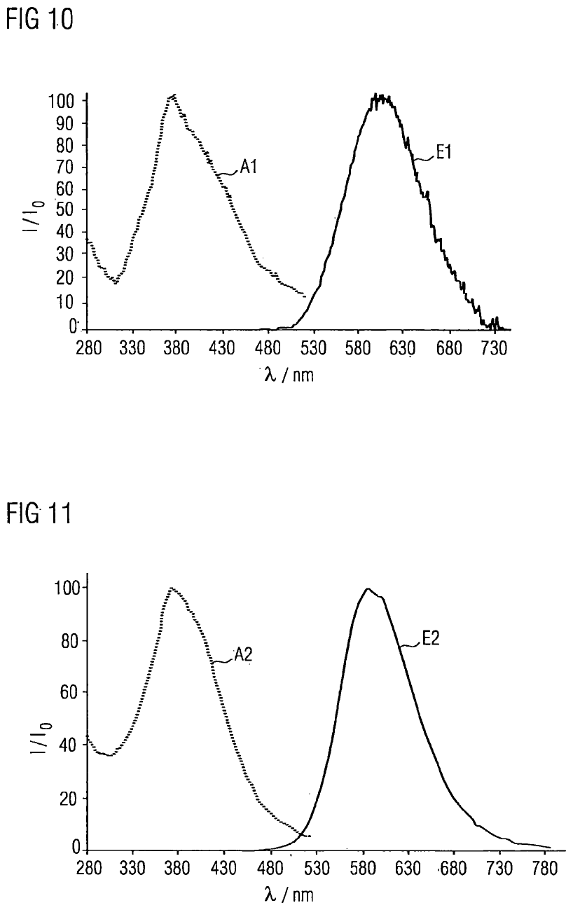

FIG. 10 shows an excitation spectrum Al and an emission spectrum E1 of a phosphor 1 according to an exemplary embodiment. The phosphor 1 presently comprises the molecular formula Li₂[Li₄Si₂N₂O₄]:Eu²⁺. The spectra A1 and E1 are shown in a wavelength range of between and including 280 nanometers and 780 nanometers. The excitation spectrum A1 was measured for wavelengths of between and including 280 nanometers and 520 nanometers. The emission spectrum E1 was measured for wavelengths of between and including 470 nanometers and 750 nanometers. The emission spectrum E1 was measured at an excitation wavelength of about 400 nanometers. The excitation spectrum reflects the intensity of an emission wavelength as a function of the excitation wavelength. In particular, the excitation spectrum is not the same as the absorption spectrum. The raw data maximum of the emission is generally selected as the emission wavelength. Presently, the excitation spectrum A1 is recorded for an emission wavelength of about 590 nanometers. From the emission spectrum E1 of phosphor 1 with the molecular formula Li₂[Li₄Si₂N₂O₄]:Eu²⁺ an emission maximum at about 606 nanometers can be determined. Further optical data of phosphor 1 are summarized in Table 7.

FIG. 11 shows an excitation spectrum A2 and an emission spectrum E2 of a phosphor 1 according to a further exemplary embodiment. The phosphor 1 comprises the molecular formula Li₃[Li₃Si₂N₂O₄]:Eu²⁺. The spectra A2 and E2 are shown in a wavelength range of between and including 280 nanometers and 780 nanometers. The excitation spectrum A2 was measured for wavelengths of between and including 280 nanometers and 520 nanometers. The emission spectrum E2 was measured for wavelengths of between and including 430 nanometers and 780 nanometers. The excitation spectrum A2 is recorded for a wavelength of about 568 nanometers. The emission spectrum E2 was measured at an excitation wavelength of about 448 nanometers. The phosphor 1 comprises an emission maximum at about 587 nanometers. Further optical data of phosphor 1 are summarized in Table 7.

TABLE 7
Optical data of Li₂[Li₄Si₂N₂O₄]:Eu₂⁺ and
Li₃[Li₃Si₂N₂O₄]:Eu²⁺.

| | Li₂[Li₄Si₂N₂O₄]:Eu²⁺ | Li₃[Li₃Si₂N₂O₄]:Eu²⁺ |
|---|---|---|
| LER/lm | 342 | 391 |
| W_{opt.}⁻¹ | | |
| λₘₐₓ/nm | 605.9 | 586.5 |
| λ_{dom}/nm | 588.0 | 583.1 |
| FWHM/nm | 99.6 | 92.7 |
| CIE-x | 0.562(1) | 0.530(1) |
| CIE-y | 0.436(1) | 0.464(1) |

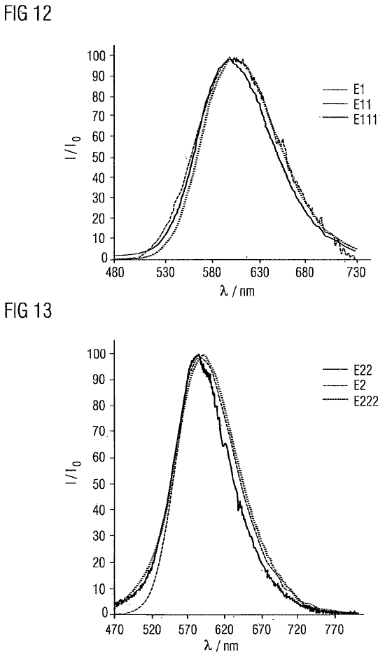

FIG. 12 shows emission spectra E1, E11, and E111. The emission spectra are shown in a wavelength range of between and including 480 nanometers and 730 nanometers. The emission spectra E1, E11, and E111 are each based on the phosphor 1 with the molecular formula Li₂[Li₄Si₂N₂O₄]:Eu²⁺. The emission spectrum E1 is recorded with an excitation wavelength of about 400 nanometers, whereas the emission spectra E11 and E111 are measured at an excitation wavelength of about 448 nanometers. The emission spectra E1 and E111 are measured on powder samples, the emission spectrum E11 on a single crystal.

FIG. 13 shows emission spectra E2, E22, and E222 each in a wavelength range of between and including 470 nanometers and 800 nanometers. The emission spectra E2, E22, and E222 were recorded for the phosphor 1 with the molecular formula Li₃[Li₃Si₂N₂O₄]:Eu²⁺. The emission spectrum E222 is recorded with an excitation wavelength of about 400 nanometers, whereas the emission spectra E2 and E22 are measured at an excitation wavelength of about 448 nanometers. Emission spectra E2 and E222 are based on powder samples, while emission spectrum E22 is based on a single crystal. The emission spectra show that the emission of phosphor 1 is slightly dependent on the excitation wavelength.

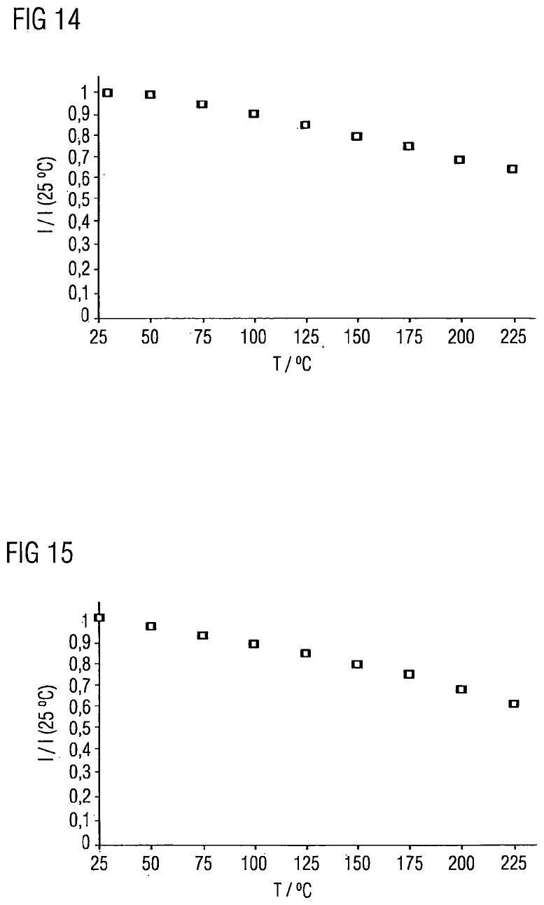

FIGS. 14 and 15 each show the temperature behavior of a phosphor 1 according to an exemplary embodiment. FIG. 14 is based on phosphor 1 with the molecular formula Li₂[Li₄Si₂N₂O₄]:Eu²⁺, FIG. 15 is based on phosphor 1 with the molecular formula Li₃[Li₃Si₂N₂O₄]:Eu²⁺. The temperature in °C is plotted on the x-axis and the quotient of the integral intensity of the emission at the current temperature and that at 25 °C is plotted on the y-axis. The step size is 25 °C in each case up to a maximum temperature of 225 °C Both phosphors 1 show a decrease in intensity with increasing temperature. However, at typical operating temperatures of radiation-emitting devices of around 125 °C, the relative intensity is still greater than 85%.

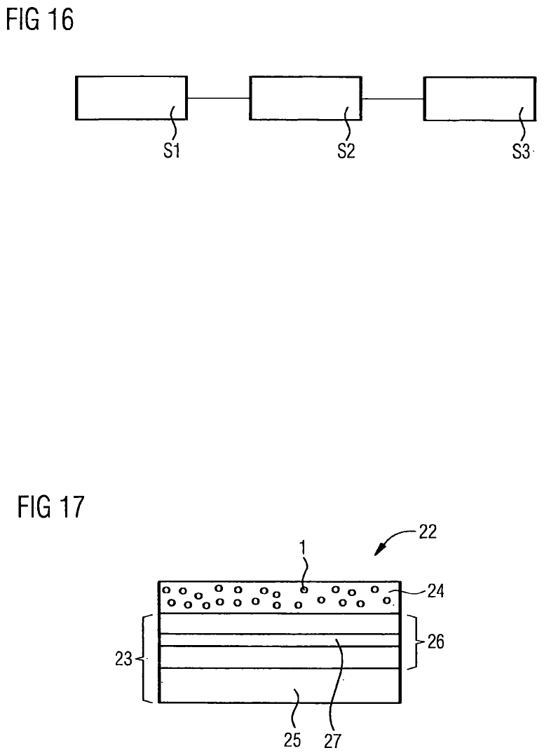

A method for producing a phosphor 1 according to an exemplary embodiment is described with reference to FIG. 16. In a first method step S1, reactants are provided. The reactants are selected from a group consisting of Si, Si₃N₄, Li₂SiN₂, SiO₂, Li₂O, Li₃N, LiN₃, LiF, Eu, EuF₂, Eu₂O₃, EuF₃, EuN, Ce, CeF₃, CeN, CeO₂, and combinations thereof. In a second method step S2, the reactants are mixed together and then, in a third method step S3, heated to a temperature in the range of between and including 800 °C and 1000 °C for a time of between and including 4 hours and 100 hours. Detailed methods are described below.

### Li₂[Li₄Si₂N₂O₄]:Eu²⁺—Variant 1

Li₂[Li₄Si₂N₂O₄]:Eu²⁺ is produced from the reactants Si₃N₄ and Li₂O in a molar ratio of 1:4 and, in particular, a flux such as LiF with 5 wt % and with EuF₂ or Eu₂O₃ to provide the activator element (Table 8, variant 1). Prior to synthesis, the reactants are intimately mixed in a glovebox under an inert gas atmosphere and then transferred to either a W or Ni crucible and reacted in a flow tube furnace or a high-frequency furnace under an N₂ atmosphere, but in particular in a Ta tube in a tube furnace. The Ta tube is tightly welded with an arc in an Ar atmosphere. The synthesis of the material takes place at a temperature of greater than or equal to 900 °C to less than 960 °C, in particular at about 960 °C, wherein this temperature is maintained for between and including 4 hours and 20 hours, for example for about 4 hours, and cooled at a rate of at least 0.3 °C/min, for example at a rate of about 0.3 °C/min.

### Li₂[Li₄Si₂N₂O₄]:Eu²⁺—Variant 2

Li₂[Li₄Si₂N₂O₄]:Eu²⁺ is formed from the reactants NaN₃, Li₂SiN₂, Li₃N, Eu₂O₃, and elemental Li as flux and reducing agent. The first four reactants are in a ratio of 2:1:1.4:0.02 (Table 8, variant 2). Prior to synthesis, the reactants are intimately mixed in a glovebox under an inert gas atmosphere to form a reactant mixture. The reactant mixture is placed in a Ta ampoule, which is sealed, transferred to a quartz glass ampoule and subjected to the following temperature program in a tube furnace: The reactant mixture is heated to about 860 °C with a heating rate of about 2 °C/min, kept at this temperature for about 100 h and then cooled to about 500 °C with a rate of about 0.1 °C/min. After reaching about 500 °C, the tube furnace was switched off and the reactant mixture was cooled to room temperature (about 10 °C/min).

### Li₂[Li₄Si₂N₂O₄]:Eu²⁺—Variant 3

Li₂[Li₄Si₂N₂O₄]:Eu²⁺ is produced from the reactants SiO₂, Li₃N, and LiN₃ in a molar ratio of 1:0.85:0.45 and, in particular, a flux such as LiF and, depending on the desired activator element, for example with EuF₂ (Table 8, variant 3). Prior to synthesis, the reactants are intimately mixed in a glovebox under an inert gas atmosphere and then transferred to a Ta tube with a welded base, which is then tightly welded. The synthesis of the material takes place at temperatures of greater than or equal to 900 °C to less than 960 °C for between and including 4 hours and 10 hours, in particular at about 960 °C and about 4 hours. The rates for cooling to room temperature are between 0.1 and 0.3 °C/min inclusive, for example at about 0.1 °C/min.

TABLE 8
Weights for producing Li₂[Li₄Si₂N₂O₄]:Eu²⁺.

| | Variant 1 | Variant 2 | Variant 3 |
|---|---|---|---|
| Si₃N₄ | 49.14 mg (0.35 mmol) | — | — |
| LiO₂ | 41.87 mg (1.40 mmol) | — | — |
| Li₃N | — | 15.25 mg | 24.37 mg |
| | | (0.438 mmol) | (0.70 mmol) |
| LiN₃ | — | — | 18.14 g |
| | | | (0.37 mmol) |
| Li₂SiN₂ | — | 21.89 mg | — |
| | | (0.313 mmol) | |
| SiO₂ | — | — | 49.46 mg |
| | | | (0.82 mmol) |
| EuF₂ | 3.99 mg (0.02 mmol) | — | 3.13 mg |
| | | | (0.02 mmol) |
| LiF | 5.00 mg (0.19 mmol) | — | 4.91 mg |
| | | | (0.19 mmol) |
| NaN₃ | — | 40.66 mg | — |
| | | (0.625 mmol) | |
| Eu₂O₃ | — | 2.20 mg | — |
| | | (0.006 mmol) | |
| Li | — | 4 mg | — |
| | | (0.576 mmol) | |

### Li₃[Li₃Si₂N₂O₄]:Eu²⁺

Li₃[Li₃Si₂N₂O₄]:Eu²⁺ is produced from the reactants Si₃N₄ and Li₂O in a molar ratio of 1:4 and, in particular, a flux such as LiF with 5 wt % and with EuF₂ or Eu₂O₃ as precursor for the activator element (Table 9, variant 1). Prior to synthesis, the reactants are intimately mixed in a glovebox under an inert gas atmosphere and then transferred to either a W or Ni crucible and synthesized in a flow tube furnace or a high-frequency furnace under an N₂ atmosphere, but especially in a Ta tube in a tube furnace. The Ta tube is tightly welded with an arc in an Ar atmosphere. The material is synthesized at a temperature of at least 960 °C, for example at about 960 °C, wherein this temperature is maintained for between and including 4 hours and 20 hours, in particular for 4 hours, and cooled at a rate of less than 0.3 °C/min, for example at a rate of about 0.1 °C/min.

### Li₃[Li₃Si₂N₂O₄]

Li₃[Li₃Si₂N₂O₄] is produced from the reactants Si₃N₄ and Li₂O in a molar ratio of 1:4 and, in particular, a flux such as LiF with 5 wt % (Table 9, variant 2). Prior to synthesis, the reactants are intimately mixed in a glovebox under an inert gas atmosphere and then transferred to either a W or Ni crucible and synthesized in a flow tube furnace or a high-frequency furnace under an N₂ atmosphere, but preferably in a Ta tube in a tube furnace. The Ta tube is tightly welded with an arc in an Ar atmosphere. The material is synthesized at a temperature of at least 960 °C, in particular at about 960 °C, wherein this temperature is maintained for between and including 4 hours and 20 hours, in particular for 4 hours, and cooled at a rate of less than 0.3 °C/min, for example at a rate of about 0.1 °C/min.

TABLE 9
Weights for producing Li₃[Li₃Si₂N₂O₄]:Eu²⁺
and Li₃[Li₃Si₂N₂O₄].

| | Variant 1 | Variant 2 |
|---|---|---|
| Si₃N₄ | 49.14 mg (0.35 mmol) | 51.28 mg (0.37 mmol) |
| Li₂O | 41.87 mg (1.40 mmol) | 43.69 mg (1.46 mmol) |
| EuF₂ | 3.99 mg (0.02 mmol) | — |
| LiF | 5.00 mg (0.19 mmol) | 5.03 mg (0.19 mmol) |

The radiation-emitting device 22 according to the exemplary embodiment of FIG. 17 comprises a semiconductor chip 23, which emits electromagnetic radiation of a first wavelength range during operation, and a conversion element 24. The semiconductor chip 23 comprises a substrate 25 on which a semiconductor layer sequence 26 is epitaxially grown. The semiconductor layer sequence 26 comprises an active region 27, which generates the electromagnetic radiation of the first wavelength range during operation of the device. The electromagnetic radiation of the first wavelength range is electromagnetic radiation in the ultraviolet to blue wavelength range of the electromagnetic spectrum. For example, the semiconductor chip 14 emits electromagnetic radiation with a dominant wavelength of about 447 nanometers.

The conversion element 24 is arranged downstream of the semiconductor chip 23 and comprises the phosphor 1. In particular, the conversion element 24 comprises no further radiation-converting component. The phosphor 1 converts the electromagnetic radiation of the first wavelength range into electromagnetic radiation with an emission spectrum. The electromagnetic radiation with the emission spectrum is at least partially different from the electromagnetic radiation of the first wavelength range. For example, Li₂[Li₄Si₂N₂O₄]:Eu²⁺ or Li₃[Li₃Si₂N₂O₄]:Eu²⁺ are used as phosphor 1.

The radiation-emitting device 22 emits mixed light composed of the electromagnetic radiation of the first wavelength range and the electromagnetic radiation with the emission spectrum.

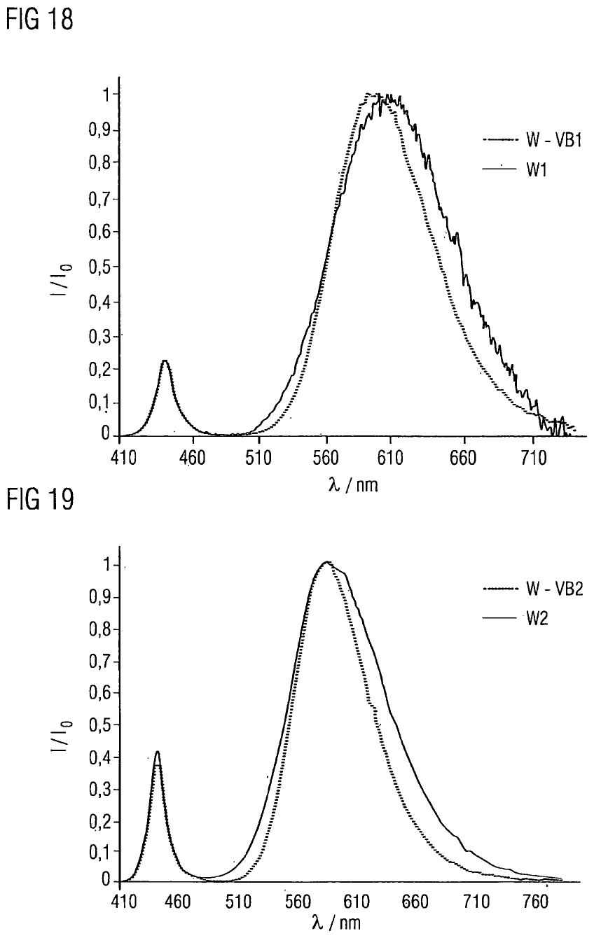

If the phosphor 1 with the molecular formula Li₂[Li₄Si₂N₂O₄]:Eu²⁺ is used in the radiation-emitting device 22, the device 22 emits mixed light with a simulated spectrum W1, as shown in FIG. 18. If the phosphor 1 with the molecular formula Li₃[Li₃Si₂N₂O₄]:Eu²⁺ is used in the radiation-emitting device 22, the device 22 emits mixed light with a simulated spectrum W2, as shown in FIG. 19. FIGS. 18 and 19 also show simulated spectra W-VB1 and W-VB2 of radiation emitting devices 22, each according to a comparative example. In the device 22 according to the comparative example with the spectrum W-VB1, the phosphor 1 (Sr_{0.4}Ba_{0.6})₂Si₅N₈:Eu²⁺ is used. In the device 22 according to the comparative example with the spectrum W-VB2, (Sr_{0.1}Ba_{0.9})₂Si₅N₈:Eu²⁺ is used as phosphor 1. The spectra are shown in a wavelength range of between and including 410nanometers and 730 nanometers or up to and including 780 nanometers, respectively. The properties of the radiation-emitting devices 22 are summarized in Tables 10 and 11.

TABLE 10
Properties of radiation-emitting devices 22 with the phosphor
Li₂[Li₄Si₂N₂O₄]:Eu²⁺ and with the phosphor (Sr_{0.4}Ba_{0.6})₂Si₅N₈:Eu²⁺.

| | Exemplary embodiment 1 | Comparative Example |
|---|---|---|
| Blue LED | 447 | 447 |
| □_{dom}/nm) | | |
| phosphor | Li₂[Li₄Si₂N₂O₄]:Eu²⁺ | (Sr_{0.4}Ba_{0.6})₂Si₅N₈:Eu²⁺ |
| CIE x | 0.535(1) | 0.535(1) |
| CIE y | 0.408(1) | 0.408(1) |
| CCT/K | 1902 | 1901 |
| CRI | 56 | 42 |

TABLE 11
Properties of radiation-emitting devices 22 with the phosphor
Li₃[Li₃Si₂N₂O₄]:Eu²⁺ and with the phosphor (Sr_{0.1}Ba_{0.9})₂Si₅N₈:Eu²⁺.

| | Exemplary embodiment 2 | Comparative Example |
|---|---|---|
| Blue LED | 447 | 447 |
| □_{dom}/nm) | | |
| phosphor | Li₃[Li₃Si₂N₂O₄]:Eu²⁺ | (Sr_{0.1}Ba_{0.9})₂ Si₅N₈:Eu²⁺ |
| CIE x | 0.489(1) | 0.490(1) |
| CIE y | 0.415(1) | 0.413(1) |
| CCT/K | 2372 | 2346 |
| CRI | 51 | 37 |

The radiation-emitting devices 22 according to the exemplary embodiments comprise a comparable correlated color temperature (CCT) and a comparable chromaticity coordinate compared to the radiation-emitting devices 22 according to the comparative examples. However, the radiation-emitting devices 22 according to the exemplary embodiments show a significantly better color rendering index (CRI).

The features and exemplary embodiments described in connection with the figures may be combined with each other in accordance with further exemplary embodiments, even if not all combinations are explicitly described. Furthermore, the exemplary embodiments described in connection with the figures may alternatively or additionally comprise further features as described in the general part.

The invention is not limited to the exemplary embodiments by the description thereof. Rather, the invention includes any new feature as well as any combination of features, which includes in particular any combination of features in the patent claims, even if this feature or combination itself is not explicitly specified in the patent claims or exemplary embodiments.

### LIST OF REFERENCE SIGNS

1 phosphor
2 host structure
3 first layer
4 second layer
5 dimer
6 LiO₃N tetrahedron
7 O atom
8 N atom
9 first chain
10 SiO₂N₂ tetrahedron
11 second chain
12 third chain
13 fourth chain
14 LiO₂N₄ octahedron
15 LiO₄ tetrahedron
16 LiO₄N₂ octahedron
17 Li atom
18 third layer
19 fifth chain
20 sixth chain
21 LiO₄N bipyramid
22 radiation-emitting device
23 semiconductor chip
24 conversion element
25 substrate
26 semiconductor layer sequence
27 active region

1. A phosphor with the molecular formula MA₁₊ₓMB₅₋ₓD₂N₂O₄:E, wherein:
MA is an element or a combination of elements selected from the group formed by Li, Na, K, Rb, and Cs;
MB is an element or a combination of elements selected from the group formed by Li and Na;
D is an element or a combination of elements selected from the group of tetravalent elements;
E is at least one activator element; and
0≤x≤3.

2. The phosphor according to claim 1,
in which D is an element or a combination of elements selected from the following group: Si, Ge, Sn, Ti, Zr, and/or
in which E is an element or a combination of elements selected from the following group: Eu, Ce, Mn, Cr, Ni, Bi, Tb, Yb.

3. The phosphor according to claim 1, in which E comprises a proportion of between and including 0.01 mol % and 10 mol %, based on an added amount of substance of MA and MB.

4. The phosphor according to claim 1,
in which MA and MB comprise the same element.

5. The phosphor according to claim 1, wherein MA and MB is Li and x=1 or x=2.

6. The phosphor according to claim 1,
in which a crystal structure of a host structure of the phosphor comprises a monoclinic or orthorhombic space group.

7. The phosphor according to claim 1
in which MA is fivefold and/or sixfold coordinated in the crystal structure of the host structure; and
in which MB is quadruply coordinated in the crystal structure of the host structure.

8. The phosphor according to claim 1,
in which the crystal structure of the host structure comprises at least two different layers which are arranged alternately.

9. The phosphor according to claim 1,
in which
the phosphor absorbs electromagnetic radiation in the ultraviolet to blue spectral range; and
an electromagnetic radiation emitted by the phosphor comprises an emission spectrum with an emission peak with an emission maximum in the wavelength range of between and including 545 nanometers and 645 nanometers.

10. The phosphor according to claim 1,
in which the electromagnetic radiation emitted by the phosphor comprises a dominant wavelength Adom between and including 535 nanometers and 635 nanometers.

11. The phosphor according to claim 1,
in which the emission peak of the phosphor comprises a full width at half maximum between and including 80 nanometers and 110 nanometers.

12. A method for producing a phosphor with the molecular formula MA1₊ₓMB₅₋ₓD₂N₂O₄:E, wherein
MA is an element or a combination of elements selected from the group formed by Li, Na, K, Rb, and Cs;
MB is an element or a combination of elements selected from the group formed by Li and Na;
D is an element or a combination of elements selected from the group of tetravalent elements;
E is at least one activator element; and
0≤x≤ 3;
comprising the steps:
providing reactants;
mixing the reactants to form a reactant mixture; and
heating the reactant mixture.

13. The method for producing a phosphor according to claim 12,
wherein the reactants are selected from the following group: elements of MA, MB, D, and E, oxides of MA, MB, D, and E, nitrides of MA, MB, D, and E, fluorides of MA, MB, D, and E, and combinations thereof.

14. The method for producing a phosphor according to claim 12,
wherein the reactant mixture is heated to a temperature between and including 800 °C and 1100 °C

15. The method for producing a phosphor according to claim 12,
wherein after heating the reactant mixture it is cooled with a rate between and including 0.1 °C/min and 10 °C/min.

16. The method for producing a phosphor according to claim 12,
wherein the reactant mixture is heated under a protective gas atmosphere.

17. The method for producing a phosphor according to claim 12,
wherein a flux is added to the reactant mixture.

18. A radiation-emitting device with:
a semiconductor chip which emits electromagnetic radiation of a first wavelength range during operation; and
a conversion element with a phosphor according to claim 1, which converts electromagnetic radiation of the first wavelength range into electromagnetic radiation with an emission spectrum.

19. The radiation-emitting device according to claim 18,
in which the conversion element comprises no further radiation-converting component.
